(19) United States
(12) Patent Application Publication
(10) Pub. No.: US 2003/0222654 A1
(43) Pub. Date: Dec. 4, 2003

(54) Cable testing, cable length, and liquid level determination system utilizing a standing wave reflectometer

(76) Inventors: Cynthia M. Furse, Salt Lake City, UT (US); Raymond J. Woodward, Windsor, CO (US)

Correspondence Address: MORRISS O'BRYANT COMPAGNI, P.C., 136 SOUTH MAIN STREET, SUITE 700, SALT LAKE CITY, UT, 84101, US

(21) Appl. No.: 10/308,864

(22) Filed: Dec. 2, 2002

Related U.S. Application Data
(60) Provisional application No. 60/335,280, filed on Nov. 30, 2001.

(51) Int. Cl. H04B 3/46; H01H 31/02; G01R 27/04

(52) U.S. Cl. 324/543; 324/637

(57) ABSTRACT

A standing wave reflectometer (SWR) that generates a standing wave on a conductor, receives a reflected standing wave, converts the reflected standing wave to a digital representation, determines a plurality of curve fitted minima of the digital representation of the reflected standing wave, and determines a location along the conductor where there is an interruption in uniformity such as at the end of the conductor, or where the conductor is touching a liquid, and thereby determine integrity of the conductor, length of the conductor, or a level of the liquid.

### CROSS REFERENCE TO RELATED APPLICATIONS

This document is a continuation of, claims priority to, and incorporates by reference all of the subject matter included in the provisional patent application filed on Nov. 30, 2001, and having serial No. 60/335,280.

### BACKGROUND OF THE INVENTION

1. Field of the Invention

This invention relates generally to the use of Standing Wave Reflectometers (SWR) to determine where a signal is reflected along a length of a conductor. More specifically, the invention relates to determining a length of a wire or cable (a conductor) or a level of a liquid by determining where along a length of the conductor that a signal is reflected, wherein reflection is a result of the signal coming to the end of the conductor, or the result of the conductor touching a liquid causing a discontinuity in impedance, wherein the invention utilizes the principles of SWR to analyze the reflected signal, and wherein the system also enables cable testing by applying the same SWR principles.

2. Description of Related Art

To understand the advantages of the present invention, it is necessary to examine relatively diverse applications of the present invention. First, the state of the art of liquid level detection is represented by a wide range of methods, including bubblers, capacitance meters, magnetic floats, radio frequency impedance techniques, radar, and differential pressure. One of the more interesting methods of liquid level detection being developed is that of Frequency Domain Reflectometry (FDR).

In FDR, instead of using signal pulses that are difficult to generate, fixed frequencies are used. An input signal is mixed with a return signal to produce a DC component at each discrete frequency being transmitted. When the DC component generated by a mixer is plotted as a function of the discrete stepped frequencies that are transmitted, a sinusoidal response can be found. By performing a Fast Fourier Transform (FFT) on the data, the distance to an obstacle or discontinuity in a cable is found to be proportional to the maximum peak index of the magnitude response. Due to the discrete nature of the FFT, the length of cable that can be measured is limited.

What is needed is a modified application of the FDR technique described above that will generate improved results by using reflected standing waves.

The second application of the standing wave technology that will be discussed is important to many industries. Specifically, wire and cable testing is a critically important industry that has significant costs and important consequences.

The benefits of being able to test cables (hereinafter to be referred to as a cables, wires, lines or conductors interchangeably) are many. Some reasons are obvious. For example, cables are used in many pieces of equipment that can suffer catastrophic failures and cause injuries. A good example of such equipment is in an passenger jet. However, the consequences of non-performance do not have to be so dire in order to see that benefits are still to be gained. For example, cables are used in many locations where they are difficult to reach, such as in the infrastructure of buildings and homes. Essentially, in many cases it is simply not practical to remove cables for testing, especially when this action can cause more damage than it prevents.

Given that the need for cable testing is important and in some cases imperative, the question is how to perform accurate testing that is practical, meaning relatively inexpensive and requiring a reasonable amount of effort. The prior art describes various techniques for performing cable testing. One such technique is time domain reflectometry (TDR). TDR is performed by sending an electrical pulse down a cable, and then receiving a reflected pulse. By analyzing the reflected pulse, it is possible to determine cable length, impedance, and the location of open or short circuits.

One of the main disadvantages of TDR is that the equipment required to perform time analysis of a reflected signal is expensive and often bulky. These factors of cost and size can be critically important. A less costly and bulky system can be used in more places, more often, and can result in great savings in money spent on performing maintenance functions, and by replacing equipment before failure.

Consider the airline industry. Miles of cabling inside a single airplane is extremely difficult to reach and test. If the cabling is removed for testing, the cabling can be damaged where no damage existed before. Thus, testing can result in more harm than good when cabling must be moved to gain access. But the nature of cable carrying conduit in an airplane simply makes access with bulky testing equipment difficult. However, if the electronics for testing cables can be made relatively small, inexpensive, and provide extremely accurate results without great effort in accessing the cables, then testing could become more frequent, and reliability improved.

Thus, it would be an advantage over the prior art to provide a system that utilizes SWR techniques to determine cable characteristics such as integrity, length and impedance. The concepts of cable testing, and cable length determination, and cable impedance determination can all be made apparent by examining an application of the SWR techniques as applied to liquid level determination.

### BRIEF SUMMARY OF THE INVENTION

It is an object of the present invention to provide a system of hardware and software that enables the determination of cable integrity using SWR techniques.

It is another object of the present invention to provide a system of hardware and software that enables the determination of cable length using SWR techniques.

It is another object of the present invention to provide a system of hardware and software that enables the determination of cable impedance using SWR techniques.

It is another object of the present invention to provide a system of hardware and software that enables the determination of the height of a liquid in a container using SWR techniques.

In a preferred embodiment, the present invention is a standing wave reflectometer (SWR) that generates a standing wave on a conductor, receives a reflected standing wave, converts the reflected standing wave to a digital representation, determines a plurality of curve fitted minima of the digital representation of the reflected standing wave, and determines a location along the conductor where there is an interruption in impedance uniformity such as at the end of the conductor, or where the conductor is touching a liquid, and thereby determine integrity, length, or impedance of the conductor, or a level of the liquid.

These and other objects, features, advantages and alternative aspects of the present invention will become apparent to those skilled in the art from a consideration of the following detailed description taken in combination with the accompanying drawings.

### BRIEF DESCRIPTION OF THE SEVERAL VIEWS OF THE DRAWINGS

FIG. 1 is a block diagram of the basic hardware elements as set forth in the preferred embodiment that is made in accordance with the principles of the present invention.

FIG. 2 is a plot of a comparison of theoretical and actual standing waves.

FIG. 3 is a plot of a typical standing wave with a short circuit termination as a function of frequency.

FIG. 4 is a block diagram of the control flow for a hardware interface.

FIG. 5 is a table of Chebyshev low-pass filter component values.

FIG. 6 is a low-pass filter schematic that is made in accordance with the principles of the present invention.

FIG. 7 is a plot of simulated and measured values for a 9^{th} order Chebyshev low-pass filter.

FIG. 8 is a plot of output power as a function of frequency for a Direct Digital Synthesizer (DDS) and a low-pass filter.

FIG. 9 is a plot of input return loss for a transformer.

FIG. 10 is an elevational profile view of a hardware configuration for determining termination resistance.

FIG. 11A is a plot of the transition from a coaxial line to ladder line without impedance matching.

FIG. 11B is a plot of the transition from a coaxial line to ladder line with impedance matching.

FIG. 12 is a block diagram of control flow for the software interface of the present invention.

FIG. 13A is a plot of clock sequences for resetting the DDS.

FIG. 13B is a plot of clock sequences for inputting a control word to the DDS.

FIG. 14 is a plot of standing waves over the extremes of a ladder line.

FIG. 15 is a plot of a standing wave, and the first, second, and third minimums with discrete voltage levels.

FIG. 16 is a plot of the first, second and third minimums in a QR curve fit.

FIG. 17 is a plot of the first, second and third minimums as calibration data points with a least squares line fit.

FIG. 18 is a plot of the first, second and third minimums as calibration data points with a 4^{th} order least squares fit.

FIG. 19 is a schematic diagram of a transformer and low-pass filter.

### DETAILED DESCRIPTION OF THE INVENTION

Reference will now be made to the drawings in which the various elements of the present invention will be given numerical designations and in which the invention will be discussed so as to enable one skilled in the art to make and use the invention. It is to be understood that the following description is only exemplary of the principles of the present invention, and should not be viewed as narrowing the claims that follow.

The presently preferred embodiment of the invention is a system that includes both hardware and software to apply SWR techniques to the determination of the location of an impedance discontinuity along a length of a conductor that in turn is used to determine cable integrity, cable length, cable impedance, and level of a liquid in a container. It is known in the prior art to utilize an SWR circuit for determining an impedance discontinuity. However, the prior art fails to recognize certain principles and aspects of the present invention, and thus the prior art fails to realize the benefits that can be obtained from the SWR circuit and software of the present invention. Thus, the broadest aspect of the present invention is how the results of the SWR circuit are used to obtain this desired information.

An overview of the SWR system of the present invention is as follows. A frequency generator transmits a plurality of discrete sinusoidal waves down a conductor. The conductor in this example is disposed so that a first end is in a liquid whose level is to be measured. Due to a change in impedance in the conductor, a reflection of the transmitted signal occurs at the point where the conductor meets the surface of the liquid. A measurement is performed of the combined transmitted and reflected signals. The combined signal, called a standing wave, has multiple peaks and troughs over a range of measured frequencies. By measuring the frequency difference between the peaks, the length to the top of the liquid is determined according to the formula of x=v/2Δf, where x is the distance from the top of the liquid to the electronics of the system, v is the velocity of propagation of the conductor in air, and Δf is the frequency between the peaks. It is noted that there are several modifications to the basic system that can be made to improve resolution of the measurement.

Now, with the basic system described above, it is now possible to describe some of the differences between the present invention and the prior art. First, it is noted that the prior art utilizes a single peak and a single null to determine the length of the conductor, or more specifically, the length of the conductor from the signal generator to a location where there is a change or discontinuity in impedance. This change in impedance indicates where the conductor touches the liquid, or the location of the end of the wire.

It is the assumption of the prior art that no better results can be obtained from using measurements other than the single peak and the single null to determine the distance to a discontinuity in impedance on the conductor. It has been assumed that all of the peaks and nulls would give the same information. However, the inventors of the present invention have determined that the prior art falls far short of its potential to determine where an impedance discontinuity is located on a conductor because of this false assumption. Thus, where the prior art is able to determine the location of the discontinuity to approximately 20 cm, the present invention is capable of determining the location of the discontinuity to approximately 1 mm.

Accordingly, it is a first aspect of the present invention that multiple peaks and nulls must be used to determine the location of the change in impedance on a conductor. What may not be apparent to those skilled in the art is that what is obtained is a 4^{th} order non-linear curve.

It is useful to understand that the present invention is capable of liquid level determination because air and water have different electromagnetic properties. When an incident electrical wave encounters a transition from air-to-water in an unshielded transmission line, a reaction occurs. The combination of an incident wave and a reflected wave is called a standing wave. A standing wave depends upon several variables. The amplitude of the standing wave has maxima and minima that occur at predictable locations on the transmission line that are dependent upon the frequency of the incident wave, the transmission line length, and the way the transmission line is terminated.

With this introduction to the principles of the present invention, it is possible to examine the details of implementation. In the examples given, it is assumed that the hardware is being utilized to determine a level of liquid in a container. Nevertheless, it should be remembered that the principles explained in this application of the present invention are equally applicable to the determination of all other aspects of a wire previously discussed, such as the determination of the length of a wire.

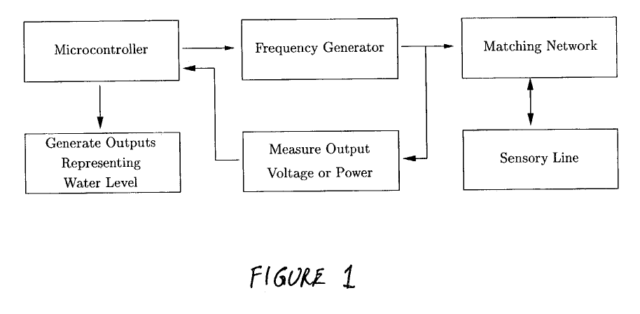

FIG. 1 is provided as a block diagram showing the basic elements of the present invention. By using a microcontroller, a frequency generator will sweep through discrete frequencies that will be sent into a conductor. Reflected waves on the conductor will result due to the change in impedance of the conductor in water as compared to its impedance in air. By the nature of the reflections that are generated, characteristics will be noted using power or voltage measurements. By using the characteristics that are found to be indicative of the liquid level, the level of liquid will be determined and output by the system.

Previous attempts at liquid level measurements using SWR techniques only utilized the first measured maximum or minimum. Advantageously, the present invention measures and utilizes a plurality of minima measurements. Then, the system utilizes curve-fitting techniques to determine the location of each minimum. This method has proven particularly effective in the presence of noise.

The present invention relies on the principle of a standing wave ratio. The standing wave ratio of a matched line is 1, while a short or open circuited line has a standing wave ratio of infinity.

For a given frequency of excitation, the nulls occur at every half wavelength from the location of the short. A familiar analogy is a jump rope tied to a doorknob. The doorknob represents the short circuit termination, the length of the rope is comparable to the line length, and the excitation is determined by the rate that energy is placed on the line. When the rope has oscillations at a particular fundamental frequency, there is a location where the rope remains still while at other locations the rope has a large change in position. Each multiple in the frequency of oscillation from the fundamental frequency will introduce an additional null in the length of the rope. The frequencies that are multiples of the fundamental frequency are referred to as harmonics. If the rate of oscillation is known when a certain number of nulls are present on the line, then the length of the rope can be determined because the termination is already known to be a short.

An air-to-liquid boundary in an unshielded sensory line is not a perfect short, but the location of the discontinuity can be determined and utilized by finding the minima in the standing wave.

The reflection is the parameter that is providing the information about where the air-to-liquid transition occurs. The larger the standing wave ratio, the better or more reliable the results will be. Thus, for a small standing wave ratio, the location of each minimum is not as discernible as it would be if the standing wave ratio were larger.

It is generally more difficult to measure voltage as a function of position. Although fundamentally the results are equivalent, the method that is used in the invention is to measure the voltage of the standing wave at the input to the line as a function of frequency. With the wide variety of frequency sources that are currently available, frequency is an easy parameter to sweep. Measuring voltage at a fixed location is also a trivial task.

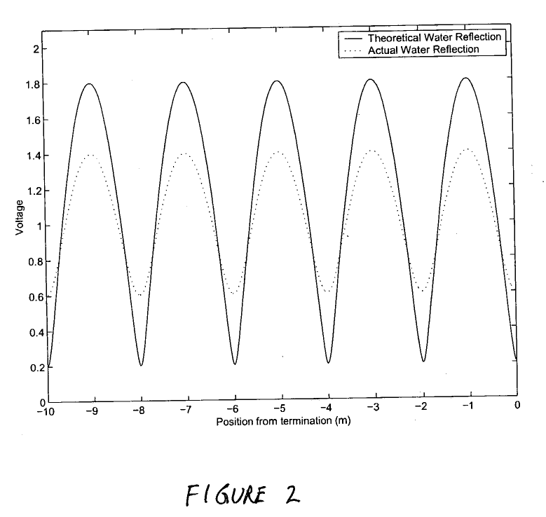

The standing wave has frequency minima that are representative of the length of the conductor to the reflection, in this case the top of the liquid. FIG. 2 is provided as a plot of a comparison of theoretical and actual standing waves.

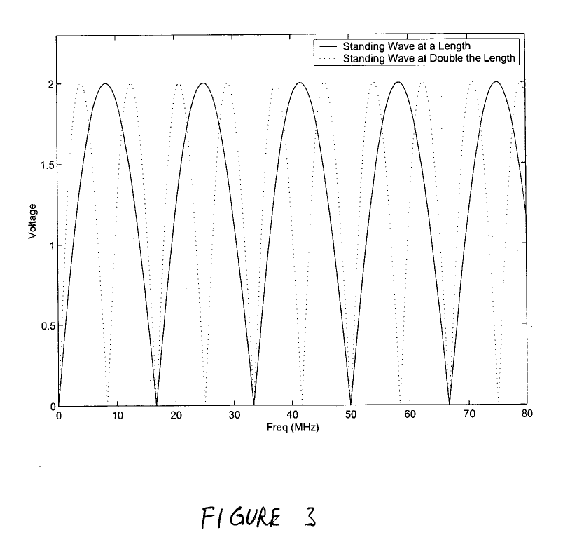

A plot of a typical standing wave with a short circuit termination as a function of frequency is shown in FIG. 3. As the length of the conductor increases, the fundamental frequency minimum and each of the respective harmonics can be seen to decrease in frequency. The result is an inverse relationship between the frequency of the minima and the conductor length.

What has been determined is that in theory, the first minimum is sufficient to accurately determine the level of the liquid, and the rest of the minima are redundant information because they are simply harmonics of the first minimum. However, experimental data illustrates that each minimum for a given liquid level provides information that is used to predict the level of the liquid in a non-ideal, noisy environment.

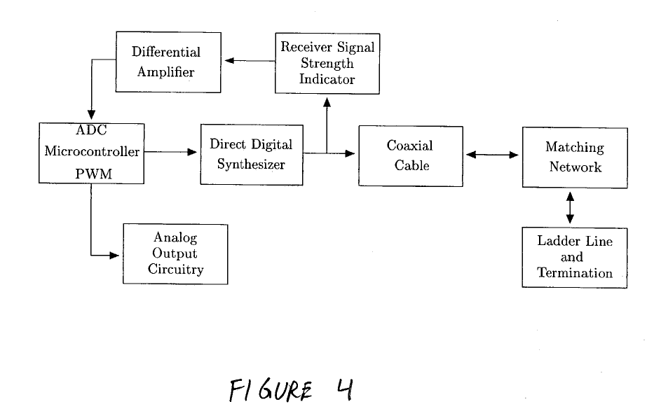

The building blocks of the system of the present invention are a microcontroller, a frequency synthesizer, a low-pass filter, a logarithmic amplifier, a differential amplifier, and an impedance matching transformer disposed between a coaxial line and a ladder line. A block diagram of the system hardware is shown in FIG. 4.

The microcontroller serves several purposes. It provides the control words for the frequency synthesizer, takes samples from the logarithmic amplifier, which is also known as a Received Signal Strength Indicator (RSSI) chip, and performs the algorithms necessary to find the minima in the standing wave and interpret them as a water level. For this application, the microcontroller requires 128 kB of EEPROM memory for the code storage space, 64 kB of RAM for data space, digital outputs for control of the frequency generator, an internal or external 12-bit Analog-to-Digital Converter (ADC), and hardware for use in generating analog outputs such as PWM outputs or an internal or external Digital-to-Analog Converter (DAC) The microcontroller needs to have the capability of performing floating point arithmetic to facilitate the algorithms that will be described. As denoted by the name of the device, the control of the entire system is performed by the microcontroller.

For the purposes of naming an example, the current microcontroller that is being used is the Tattletale Model 8, TT8. It provides all of the essential requirements listed. In considering monetary constraints, future revisions of the system should use a less expensive, but equally acceptable, controller.

In order to perform a frequency sweep, an oscillator that can produce many different frequencies at a consistent power level is necessary. Some of the considerations that need to be addressed when choosing between different varieties of oscillators or synthesizers are: the desired range of frequencies, the smallest required step size between frequencies, the necessary output power, and the method used to tune between frequencies. Other traits can be evaluated like the phase noise, harmonics, settling time, and ease of use. In this example, a Phase Lock Loop (PLL) synthesizer and a Direct Digital Synthesizer (DDS) are used.

The PLL makes use of several different components in order to produce a controllable frequency. The required components are a Local Oscillator (LO), a phase comparator, a low-pass filter, a Voltage Controlled Oscillator (VCO), and a pair of digitally controlled dividers. Generally, a PLL synthesizer chip can be found that has all of the components integrated except for the LO, VCO, and low-pass filter. Each PLL synthesizer chip will have bandwidth limits that restrain the choice of the VCO. The cost and low power dissipation of a PLL synthesizer are some of its main advantages. There are many features that are less than desirable, though. Some results that come from the use of a VCO are: harmonics of the fundamental frequency, a varying output power as a function of the output frequency, and a settling time that is dependent on the VCO tuning time along with the time constant of the loop filter. The PLL's settling time is usually >1 ms. Another undesirable feature is the output phase noise that is a multiple of the phase noise of the reference oscillator.

A DDS chip boasts an agile and accurate frequency while maintaining low distortion in the output waveform. Its cost and power dissipation are comparable to those of the PLL synthesizer circuits. A reference clock oscillator and a low-pass filter are required externally. The output frequency is set using a frequency control word to a fraction of the system clock rate using digital signal processing techniques. The digital sine wave is changed to an analog sine wave using a DAC. The output waveform is then passed through an external low-pass filter to remove the image frequencies that result from the signal processing that has been performed previously. The phase noise of the output waveform is lower than the phase noise of the frequency reference oscillator and is only dependent on the bit resolution of the DAC. Because the output frequency is only dependent on the signal processing delays, the output frequency is accurate a mere 60 μs after issuing the frequency update command. Though there is generally a slowly decreasing slope in the output power as the frequency increases, the output power level remains relatively constant.

For the current design, the AD9851 DDS frequency synthesizer from Analog Devices is used. Using a 30-MHz reference clock with the six times multiplier engaged, the internal system clock runs at 180 MHz. The allowable frequencies are 1 to 90 MHz. Because it utilizes a 32-bit frequency control word, the resolution is approximately 40 MHz. The stability of the frequency that is output is dependent on the reference clock. Because the reference clock can be multiplied, a more stable, lower frequency reference is utilized in conjunction with the six times reference multiplier to produce a more stable output frequency. A 10-bit DAC is used in conjunction with the six times reference multiplier resulting in a phase noise of −125 dBc/Hz. The spurious-free dynamic range is below −43 dBc for operation at 70 MHz analog output in the worst case with a better spurious-free dynamic range at lower frequencies. The output power has less than 1 dB of variation over the whole tuning range. Its output values currently range from −7 to −8 dBm. The output power level can be improved by making use of the chip's differential current outputs.

An ideal low-pass filter would allow the DDS frequency synthesizer to use the full output range from 1-90 MHz. Because an ideal low-pass filter is not realizable, a close approximation can be made by using a high order filter. Several different possibilities are available when considering different filters. Different varieties are realized using binomial, Chebyshev, and elliptical coefficients to compute components of the filter. The steps involved in designing a filter are: 1. Determine desirable characteristics of the filter, 2. Choose a low-pass prototype from the available filter coefficients, 3. If necessary, convert from a low-pass to a high pass, a band pass, or a notch filter, and 4. Scale the coefficients so that the cutoff frequency or pass band is as desired.

Each of the different types of filter coefficients has its relative advantages and disadvantages. A filter that makes use of binomial coefficients is maximally flat, meaning that there is no ripple in the pass band. The Chebyshev filter allows a certain amount of ripple in the pass band, and as a result has a faster cutoff than the maximally flat filter. When a larger amount of ripple is allowed, a cutoff that is steeper is obtained. The elliptical filter has a set amount of ripple in the pass band, a steep cutoff, and a stop band noise floor that can be set at a particular level. A trade-off between steep cutoff and noise floor level is made in the case of the elliptical filter. Selecting a lower noise floor results in a cutoff that is less steep than when a higher relative noise floor is chosen.

The current design makes use of a 9th order Chebyshev filter. It has been chosen due to its steep cutoff. The pass band ripple has been selected as 0.5 dB. Because both the prototype filter and the desired filter are low pass, no transformation is required.

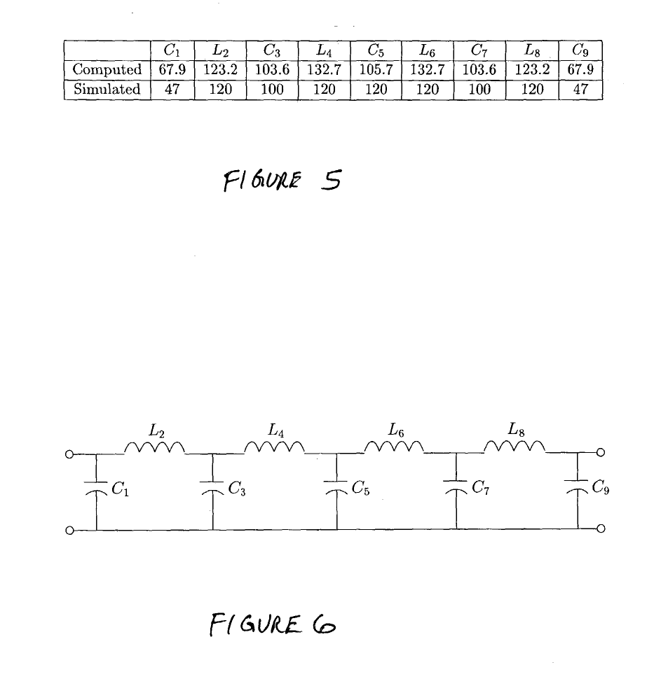

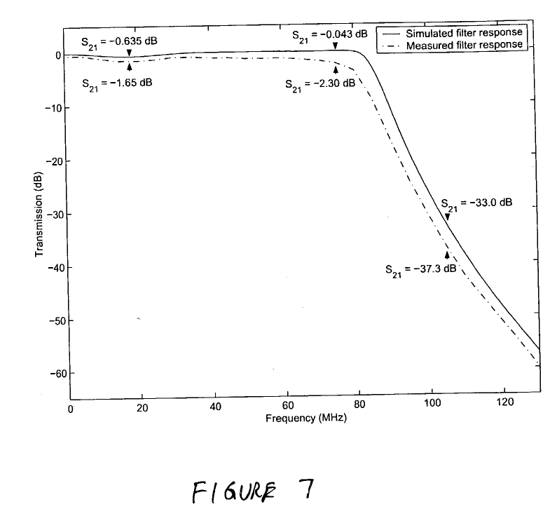

In order to find the components for a filter at a particular cutoff frequency, the Chebyshev coefficients are scaled. This particular filter is designed for a load impedance of R=50 and a cutoff frequency at fc=82 MHz. Using these parameters and coefficients in the equations above, the capacitances and inductances for the filter are found to be those in FIG. 5. The prototype schematic for the lumped element filter is shown in FIG. 6.

Because the exact values that have been computed in the first line of the equation are not standard capacitance and inductance values, they must be modified to values that can be purchased.

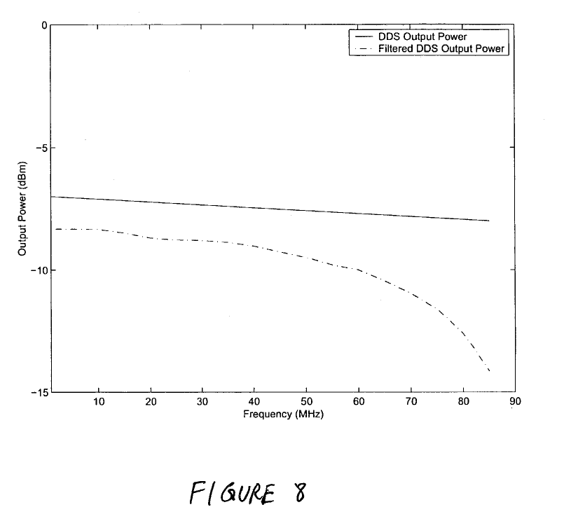

The simulated response of the filter is shown in FIG. 7. The cutoff frequency for the simulated response curve is about 82 MHz as expected.

An important part of the design is the value of the response at the image frequency of the desired frequency value. Because the DDS system clock operates at 180 MHz with a 30-MHz local oscillator, the images reflect around the frequency of 90 MHz, half the system clock rate. A desired frequency of 75 MHz within the pass band of the filter has an image frequency at 105 MHz. While the simulated output power of the filter at 75 MHz is only attenuated by about 0.043 dB, the output power at 105 MHz is attenuated by 33.0 dB. Using the same component values as those specified, surface mount chips were used to populate the board.

In FIG. 7 a plot of the actual filter response is also shown. The cutoff frequency of the tested filter is at about 80 MHz. Some differences are present due to the non-ideality of the tested filter; however, the tested filter does have a good resemblance to the simulated filter.

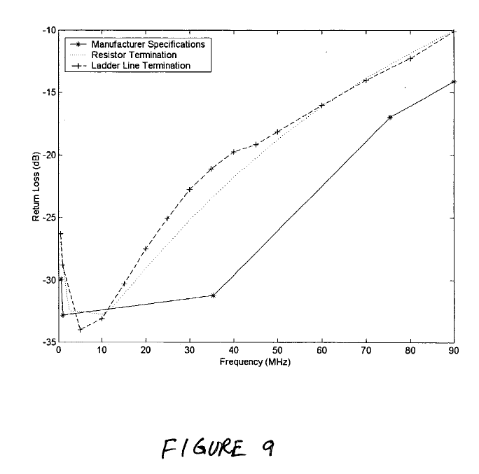

From a system perspective, it is important to know the amount of power that is present at the output of the low-pass filter when the DDS synthesizer is attached to the input of the filter. This output power as a function of frequency is shown in FIG. 8. The power that is available to the rest of the system is seen to be greater than −9 dBm for frequencies lower than 40 MHz. Though this power level is small, it has been found to be sufficient for the current design of the system.

Two other filters were designed prior to the design of the 9th order filter. The first filter is a 5th order Chebyshev filter. Two reasons that it is not being used currently are a less steep cutoff due to the 5th order nature, and a cutoff frequency that has been placed at 90 MHz. A frequency lower than 90 MHz is desirable because image frequencies that are not sufficiently attenuated adversely affect the standing wave. The second filter is a 7^{th} order elliptical filter. The simulated response for the filter is very promising, but when the standard components are placed on the board where the components are no longer ideal, the filter does not operate correctly. A 7th order elliptical filter makes use of 10 components, and although the cutoff of the filter is steeper than that of the 9th order Chebyshev filter, it is not replicable.

The whole basis for this method of measuring water level is contingent upon the capability of accurately measuring the minima in the standing wave. There are several different ways that a voltage or power level can be measured at a particular point. They include: a detector diode with an integrating capacitor, an RMS to DC converter circuit, a super diode circuit, and a Receiver Signal Strength Indicator (RSSI) chip. The first three circuits represent linear power in a linear fashion. The RSSI chip, however, represents the decibel power level present at its input as a linear DC output.

Of the four circuits listed, the most simple is a peak rectifier circuit. An RC time constant is chosen so that the power signal present is well represented. The trade-offs in the selection of the time constant are the ripple in the output signal and the amount of time necessary for the voltage stored in the capacitor to drain when a change at the input occurs. The ripple is found as

$${V}_{r} = \frac{{V}_{p}}{fRC}$$

where Vr is the ripple, and Vp is the peak voltage. Many different kinds of diodes can be used in this type of design. A key constraint in choosing a diode is the frequency range of valid operation. Some additional considerations are ensuring that the circuit has a high impedance input, and using a zero bias diode or another component that will allow sufficient power to be passed to the output.

An RMS-to-DC Converter is a viable option for use in the circuit. The main issue in finding the correct RMS-to-DC Converter is its frequency range of operation and its linear input-output range. Most RMS-to-DC Converters are for use below 10 MHz which makes them undesirable because frequencies may extend as high as 80 MHz. One RMS-to-DC Converter has been found that operates through 100 MHz. The Converter uses the heat generated by the power input to the chip and converts it to an output voltage. Some drawbacks of the chip are a slow settling time, on the order of one half second, and an inherent dependence on the ambient temperature. Many external components are required for the chip as well.

As a complex solution, the super diode ideally provides the desired result of a DC representation of the signal at its input. For its operation, a pair of amplifiers, a pair of diodes, and several other components are required. Many factors would need to go into the design of this circuitry. Besides being complex and requiring high frequency amplifiers and diodes, the circuit would require a bipolar supply. Due to these and other issues, only an initial investigation of this circuit's feasibility has been made.

The RSSI chip meets all of the design objectives for this particular circuit because it has a broad frequency of operation, makes use of a single supply voltage, and accurately represents the power at its input. A dynamic range of about 100 dB is representable by most RSSI chips with a power resolution of better than 0.5 dB. Several simple surface mount components are required externally. The necessary surface mount resistors and capacitors are inexpensive and easily implemented in a printed circuit board design.

In choosing the right device for the water level system, a deciding factor is the low power that is being used in the system. Because the power at the output of the low-pass filter is about −9 dBm for frequencies through 40 MHz, the devices that represent the standing wave measurement at the input in a linear fashion are not desirable. With a power between −2 dBm to 0 dBm, a circuit like the detector diode or one of the others would become more viable. In the present invention, an RSSI chip has been used. The particular chip that is used is the AD8309 RSSI chip. The dynamic range for the chip is from −97 to 7 dBV with a resolution of 0.4 dB.

An issue when first considering the addition of the RSSI chip to the system has been a way of not adversely affecting the power that being sent down the conductor when measuring the power level. The key factor in achieving this result is a high input impedance at the RSSI chip. A couple of different buffer circuits have been considered to reach this goal. A high input impedance is the result of adding the buffer circuitry, but the adverse effect is that both circuits produce additional harmonics. The harmonics cannot be neglected because the RSSI chip makes a measurement of the power that is present over a large frequency range from 5 to 400 MHz. As a result of the undesirable qualities of the buffer circuits, a better investigation of the RSSI properties has been made. The input impedance of the RSSI chip is about 1000 ohms. Because the characteristic impedance of the coaxial line on either side of the location where the measurement is being made is 50 ohms, the input impedance is sufficiently large to have a very small effect on the power that is used to measure the water level while not adding undesirable harmonics to the measurements.

When measuring the standing wave with the RSSI chip, the DC output of the circuit ranges from 1.60 to 1.85 V. To detect the minimum value accurately, changes in the mV range are significant. In order to measure changes with millivolt resolution, an Analog-to-Digital converter with a sufficient number of bits is required. The equation for finding the resolution of an ADC is

$$R = \frac{{V}_{high} - {V}_{low}}{{2}^{b} - 1} .$$

For this equation, R is the resolution in volts, Vhigh is the reference voltage of the ADC, Vlow is generally ground potential, and b is the number of bits that the ADC produces. In order to get a resolution less than 1 mV, 12 bits are required in the ADC. When using the ADC, the resolution has been found to vary about 8 mV above and below the desired reading instead of the desired 1 mV accuracy. This resolution has been tested using a DC battery. Because a battery has no inherent ripple in its voltage, a good approximation of the ADC resolution can be made. The output of the RSSI chip cannot be expected to be as clean as a battery, so instead of the desired 1-mV resolution, a variance of more than 8 mV can be expected.

In an attempt to reduce the error in the DC readings made by the ADC, a differential amplifier has been introduced. Because the DC voltage varies from 1.60 to 1.85 V, a value of 1.50 V is applied on the negative terminal of the amplifier, and the DC output from the RSSI chip is applied at the positive terminal. The AD606 has a default gain of 10 V/V. The resultant output voltage from the amplifier is from 1.00 to 3.50 V. As a result, a value of 10 mV is significant and though there is still a variance of 8 mV when the ADC samples the voltage, software averaging can be used in an attempt to compensate.

Coaxial line is used to carry the signal to the sensory line. The length of the coaxial line is significant because it is a part of the length to the discontinuity caused by the air-to-liquid reaction. Because the liquid could potentially reach as high as the top of the sensory line, the length of the coaxial line also places a limit on the highest frequency of the first minimum and the subsequent harmonics. Ideally, the coaxial line is lossless. The coaxial cable that is currently being used is RG-141 A/U. Some loss is inherent in the coaxial line. In the case of this particular coaxial cable, the loss is about 0.07 dB/m.

Because the characteristic impedance of the coaxial line is 50 ohms and that of the ladder line is 400 ohms, a matching network is necessary to reduce the amount of reflected power due to the change in impedance. Several approaches have been attempted prior to finding a suitable solution.

The first approach that was investigated was to use a Chebyshev filter to match the load. An analysis of this approach showed it to be inconsistent.

A second approach was to use a generic 300-75 ohm transformer that is used for television receiver applications, and adjust the number of wire wrapped turns on the ferrite core.

The final approach to matching these lines is to acquire a transformer with the proper turns ratio such as the Minicircuits ADT8-1T. Because the turns ratio of the transformer is not a simple integer value, a more complex method is used. Because the solution is not trivial, and the frequency range of operation of the transformer is also an issue, the best solution is to find a suitable part that a manufacturer has designed. When the specifications of the part are well determined, the selection process is simplified. An example of an important specification in this case is the input return loss. If the insertion loss of the transformer is significant, a reflection will result causing an undesired standing wave in addition to the desired standing wave caused by the reflection at the level of the water. By finding a frequency range where the insertion loss is significantly low, the system functions properly and the water level is determined as desired.

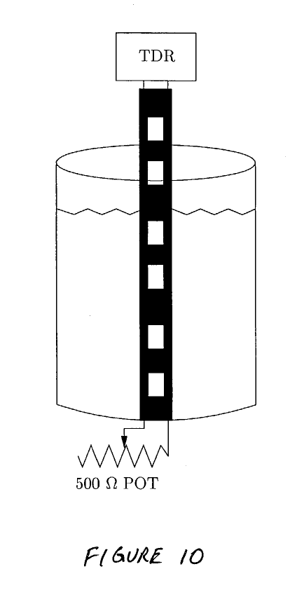

A plot showing the comparison between the Minicircuit's specifications for the ADT8-1T transformer and the measured response for the transformer with a 390-ohm resistor and a length of matched ladder line is shown in FIG. 9. When the return loss is below −20 dB, the reflections are sufficiently small to be neglected. This indicates a usable frequency range of about 40 MHz. Having performed a proper match between the 50-ohm coaxial cable and the 400-ohm ladder line, reliable bidirectional transmission can be made through the transformer.

With the lines properly matched, the issues involved in sensing the distance to the air-to-water boundary can be addressed. The sensory line is an integral component of the system because it is the portion that is affected by changes in the amount of water that is present on the line.

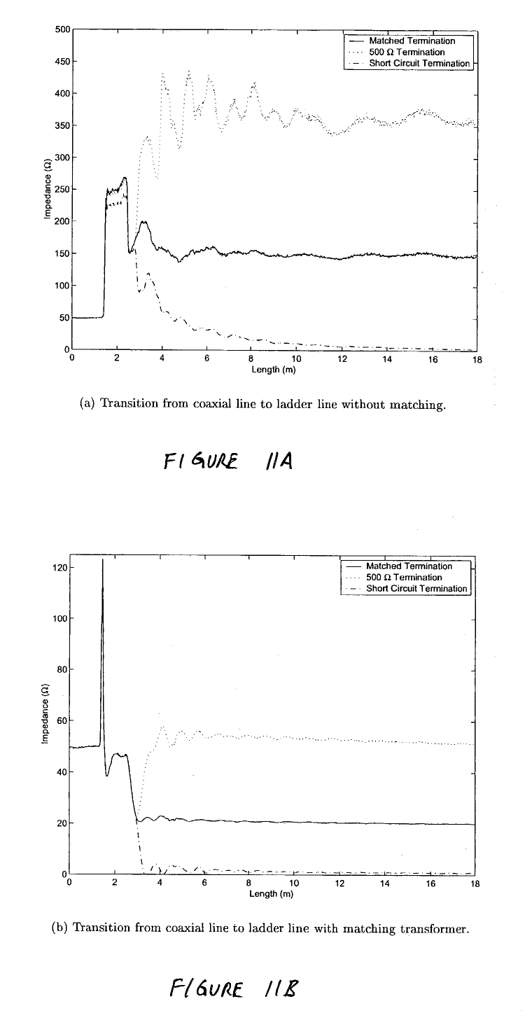

A balanced line called a ladder line is used because the separation between the two conductive lines is about 2.05 cm, and the dielectric between the lines is very thin, allowing water to have a large effect on its impedance. The characteristic impedance of the ladder line in air is about 400 ohms. In water, however, the characteristic impedance has a different value. The value of the impedance in water can be found by measuring the line in water using a Time Domain Reflectometer (TDR). One method of performing this operation is to use a container with holes to allow the stripped ends of the ladder line to be placed through them and then sealed with a glue or sealant. A potentiometer with a range of about 0 to 500 ohms can then be placed on the stripped ends, and the container with the ladder line in it can be filled with water. A diagram of the configuration can be seen in FIG. 10.

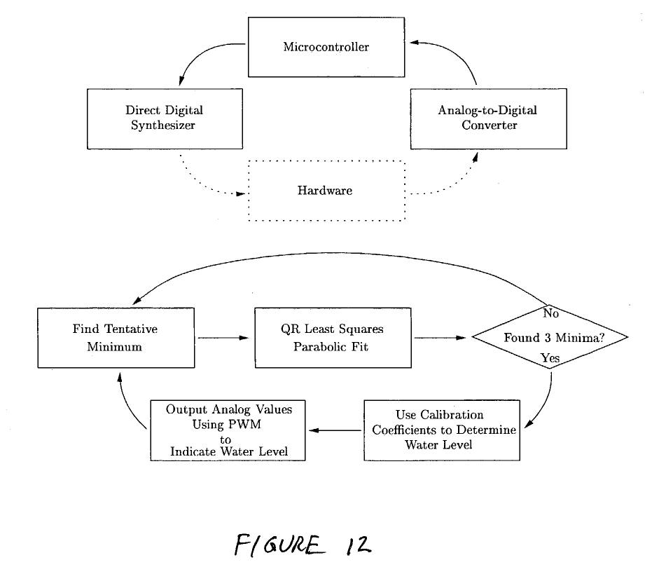

When using the TDR, impedance values can be found as a function of length. A length of coaxial line is connected on the front of the ladder line. At the transition from the coaxial line to the ladder line, an abrupt change in characteristic impedance is noted as in FIG. 11A. After some distance with the impedance of the ladder line, the impedance is seen to decrease again at the air-to-water boundary. The line is in water for a relatively small distance due to the size of the container before the potentiometer is reached. The location of the potentiometer can be found by setting the potentiometer at its extreme values. In this case, three different resistances are presented by the potentiometer. When the impedance is too large, as in the case of the 500-ohm resistance, the trace on the TDR will tend to increase, and when it is too small, as with the short termination, the trace will tend to decrease. When the trace continues flat with the impedance of the line in the water, the line is matched, and the potentiometer can be measured to find the impedance of the line in water (172 ohms). The better the match of the terminating resistor to the impedance in water, the smaller the effect of multiple reflections due to the mismatch becomes. With a change in impedance from 400 to 172 ohms, the reflection from the air-to-water boundary results in a reflection coefficient of about (−0.4). In order to match the end of the ladder line that is assumed to always be in water or at least the lowest water level to be measured, a 160-ohm resistor is placed on the end of the line and sealed using a nontoxic sealant or glue.

In FIG. 11B, a TDR plot is presented with the same terminating resistances as before except that the impedance matching transformer is placed between the coaxial cable and the ladder line. The abrupt spike that is seen at the transformer is an inductive effect that does not allow high frequency signals to pass. The impedance of the ladder line in air is nearly the desired 50 ohms. The 500 ohm and short terminations are seen to create similar mismatches to those seen before and the matched resistance continues with a virtually flat impedance value to that presented by the line in water. In all three cases, a finite amount of ripple is present. The ripple is a result of the transient response. This system does not depend on the transient response of the reflection. It makes the standing wave measurements after the system has reached its steady state value. The result is a decreased importance placed on exact timing making less expensive parts feasible.

With the coaxial line matched to the ladder line using the matching transformer, and the terminating resistor of the ladder line matched to the impedance of the ladder line in water, the hardware is in place for the standing wave measurements to be performed.

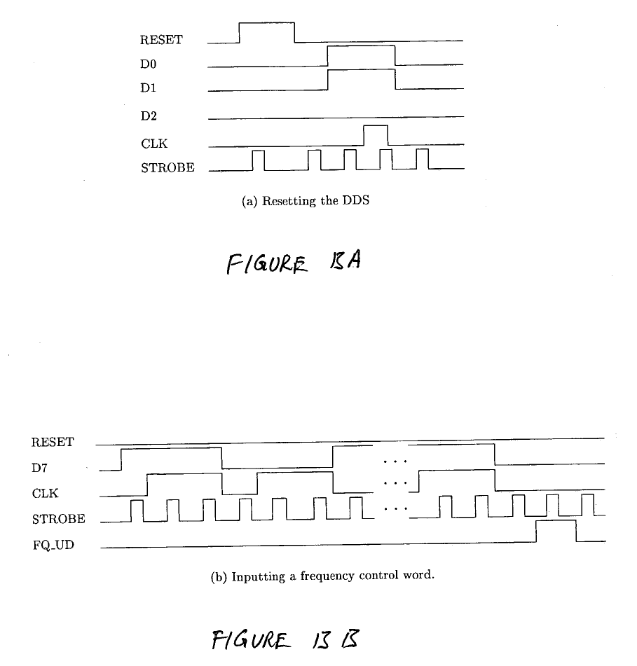

The software also performs essential functions of the present invention. The code in the microcontroller performs several operations. A block diagram of the basic software operations is shown in FIG. 12. One main portion of the software is the control of the DDS frequency synthesizer. The DDS frequency synthesizer generates a frequency on the line producing a standing wave that is measured using the RSSI and sampled by the ADC. Using the digital representations of the standing wave at each frequency, it finds tentative and curve fitted minima. From the minima, it calculates the water level using predetermined coefficients, and outputs analog values that are representative of the detected water level. The process of finding the minima and outputting the analog representation of the water level continues indefinitely as long as the system is running.

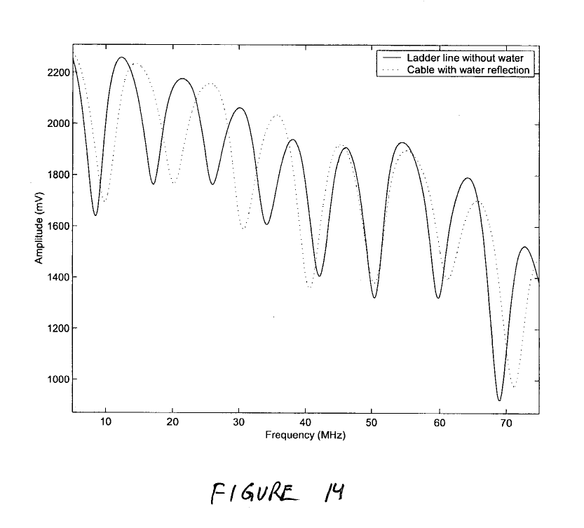

The first operation performed by the software is to reset the DDS frequency synthesizer and initialize it into serial codeword input mode. This is accomplished by asserting and deasserting the RESET pin, setting the first three data lines to the value 011, and then outputting a valid code word to the DDS chip. The timing for a reset is shown in FIG. 13A. After resetting, the frequency synthesizer can be set to any valid frequency within the range from 0 to 90 MHz as many times as desired. If another reset is desired, the same procedure must be followed. To set the DDS to a particular frequency, the following formula is used:

$${f}_{out} = \frac{( Δ P \cdot {SYS}_{CLK} )}{{2}^{32}} ,$$

where ΔP is the 32-bit phase change, SYSclk is the value of the system clock which is 180 MHz, and fout is the frequency that is to be output from the DDS chip. The timing for updating a frequency is shown in FIG. 13B. The output frequency, fout, is written to the D7 data line from LSB to MSB.

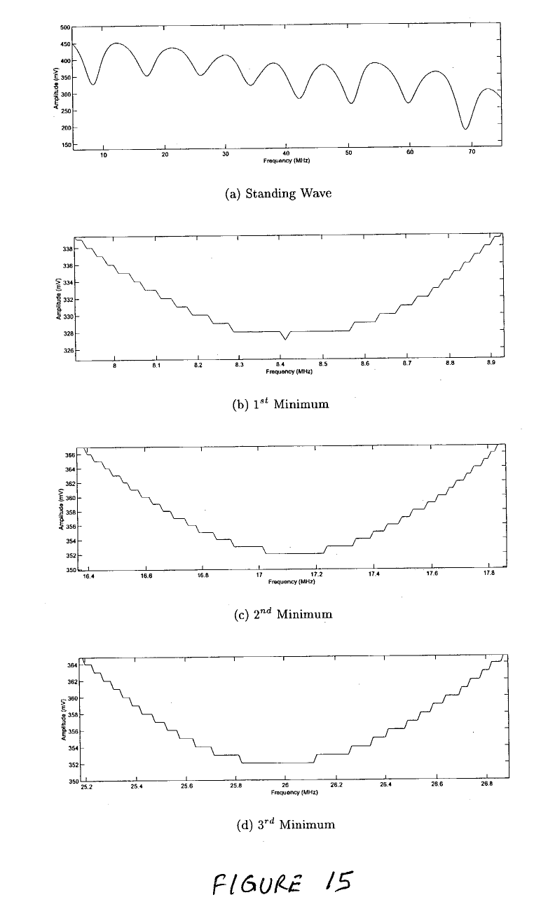

Representative standing waves generated using the hardware explained above are shown in FIG. 14. The task of finding the frequency of a minimum in the standing wave is at the heart of the system operation. There are many methods that could be used to find a tentative minimum. One method is finding a global minimum in a local range. Another method is sweeping through the frequency range while the standing wave values are decreasing until the standing wave curve starts to increase. The global minimum method is less prone to noise, but it is significantly slower and may also produce invalid results when used for more than the first three minima with the current line length configuration. Noise is a significant factor when moving across the standing wave curve in the case of the second method; nevertheless, the second method has been used to find the tentative minimum thus far.

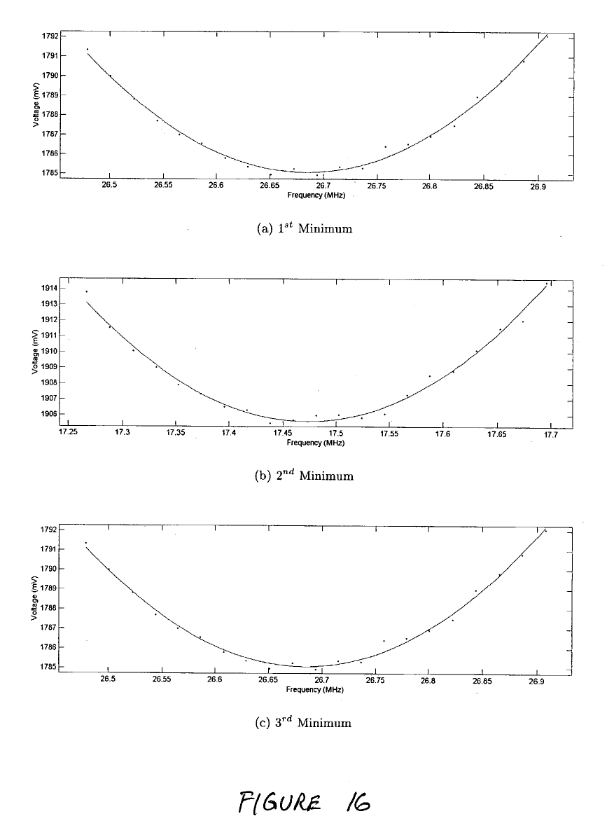

An algorithm is needed to find the minima in the standing wave. The code starts sweeping with a set frequency step size at a predetermined frequency below the lowest possible frequency minimum, as determined by the length of the coaxial cable and the ladder line. The standing wave value at each frequency is found by summing 40 values from the ADC. These values are scaled by 1200 to reduce the amount of jitter in the measurements and to give the standing wave a step-like appearance as in FIG. 15. Each time the code finds a lower step, the frequency and standing wave value of the left endpoint are saved. When an upward step is found, and it is determined not to be a glitch, the frequency of the right endpoint is saved. The tentative value of the frequency minimum is calculated as the midpoint of the left and right endpoints. The resolution of the frequency minimum value is limited to half of the frequency step size that is being used. This value for a frequency minimum could be used to calculate the water level. The discrete nature of the minima limits the accuracy of the water level that is output. Another noteworthy observation is that the values of the minima found using this algorithm seldom stay constant over time even though the water level does not change. Averaging several of the minima could be useful in finding a value that varies less as time passes, but curve fitting has been determined to remove the discreteness from the measurements in order to find an accurate value in the presence of noise.

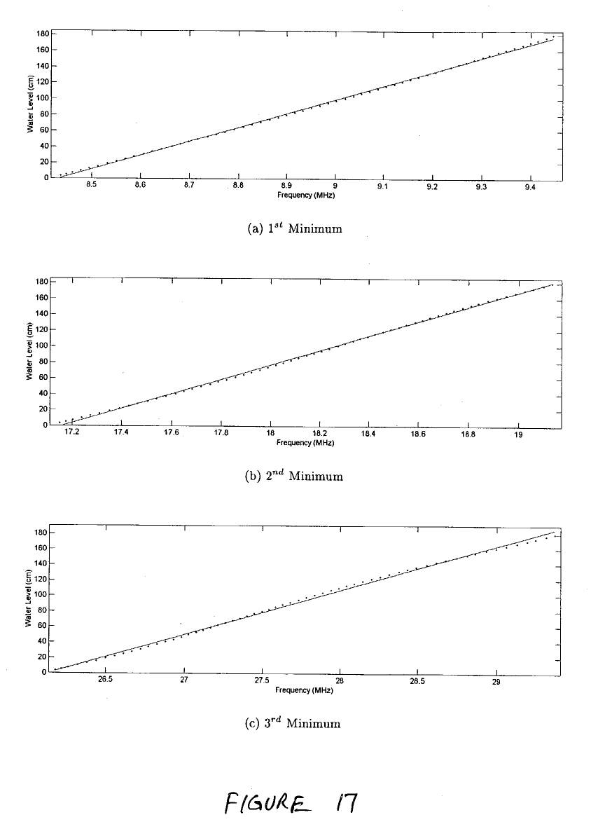

The nature of the standing wave around the minimum is very similar to a parabolic curve. The tentative minimum is found and used to define a center point for data to be taken. A window is chosen around this center frequency, and a fixed number of standing wave measurements are made at discrete frequencies. Currently, the window size is 500 kHz, and 21 discrete frequencies are used within the given window. This window size has been determined by using Matlab's™ pseudo-inverse, pinv( ), function and then minimizing the difference in the parabola and the points that the parabola fits. A plot of some actual data points along with the parabolic curve fit for each minimum is shown in FIG. 16.

The least squares equation is

$$A = [ \begin{matrix}{f}_{1}^{2} & {f}_{1} & 1 \\ {f}_{2}^{2} & {f}_{2} & 1 \\ ⋮ & ⋮ & ⋮ \\ {f}_{n}^{2} & {f}_{n} & 1\end{matrix} ] c = [ \begin{matrix}a \\ b \\ c\end{matrix} ] y = [ \begin{matrix}{y}_{1} \\ {y}_{2} \\ ⋮ \\ {y}_{n}\end{matrix} ]$$

where fm for m=1, 2, . . . , n are the discrete frequencies taken in the designated window, and the ym are the standing wave values at each discrete frequency. The vector c is the unknown coefficients for the quadratic curve fit. The equation is Ac=y.

Given the input frequencies and their respective standing wave power levels, the coefficient vector can be found by computing the pseudo-inverse of the matrix, A, and multiplying it by the measured standing wave power levels, y. Once the coefficients from the least squares solution are found, the first two coefficients are used to find the vertex of the parabola as −b/2a. As the point at the vertex of the parabola is the minimum of the function, the frequency value where the minimum occurs is found. The value of the minimum frequency is returned from the parabolic curve fit function.

Two methods have been evaluated for performing the least squares parabolic fit on-board the microcontroller. The first algorithm that has been used to calculate the parabolic fit is the LU decomposition. The advantages of using this method to find the least squares solution are its computational efficiency and a relatively smaller memory requirement because the algorithm can be performed in place. In finding the least squares solution, matrix inversion is required. The LU decomposition facilitates the inversion because it makes use of lower and upper triangular matrices. The specific method of the LU decomposition that has been attempted is Gaussian elimination with pivoting.

A major disadvantage of using this method is the ill conditioning of the matrix that is generated as the input to the algorithm. The ill conditioning comes as a result of linear equations in the rows of the matrix that are nearly parallel to one another. A small amount of error in determining the matrix can result in a very large error in the solution to the linear equations. The degree to which the matrix is poorly conditioned is quantified by its condition number. As a general rule, the number of significant digits in the solution is found by taking the difference of the precision of the calculations and the order of the condition number.

As an example, calculations performed using double floating point precision may have n=18 significant figures. A condition number of 1010 would indicate an approximate precision of eight significant figures. The condition number places an upper bound on the error that is generated when performing the matrix inversion.

Another consideration is the accuracy of the data. Because a 12-bit ADC is being used, there are only 4096 discrete values that can be represented. This indicates that the standing wave values have at most four significant figures. In addition noisy or inaccurate data can cause the solution of the matrix equation to be invalid. In the case of the matrix input to the LU decomposition function, a condition number on the order of 1010 results. With the ill conditioning of the matrix in conjunction with the small number of significant digits in the standing wave values, the solution that is generated has no significance.

Better results have been produced using a QR decomposition to implement the least squares solution. This method makes use of an orthogonal matrix Q and an upper triangular matrix R as A=QR where A is the matrix to be inverted. An orthogonal matrix has the property that QT=Q where QT is the transpose of Q. The advantage that this algorithm has over the LU decomposition is a superior matrix representation. By using the QR decomposition, the condition numbers of the matrices for the first three minima are 104, 105, and 106, respectively. However, the costs inherent in the improved numerics are a larger memory space requirement and a more computationally complex algorithm.

Because the accuracy of the frequency minima relate directly to the accuracy of the water level measurement, the expense from the extra memory and a more complex algorithm are worthwhile. The improvement in the condition number of the matrices does not guarantee an accurate answer because the noisy standing wave data from the ADC is not considered in the calculation of the condition number. By comparing the results generated by the QR decomposition in the microcontroller with the results from pseudo-inverse on the same data set in Matlab™, the first three frequency minima have been found to be accurate to four significant figures. The accuracy afforded by the parabolic fit in the presence of noise is a key component in the system's overall performance.

After finding and storing the values of the minima that are returned from the parabolic curve fit function, the values are used to determine the water level. The frequency of the minimum from the QR-fit is used as the parameter with the 4th order polynomial curve fit coefficients to find the water level. The equation follows the form of:

W(fₘ)=+c₄+c₃fₘ³+c₂fₘ²c₁fₘ+c₀

where W(fm) is the water level as a function of the minimum frequency, and c4, c3 . . . c0 are the 4th order calibration coefficients calculated for each minimum.

Because the values of each of the minima tend to vary in the third or fourth decimal place, averaging consecutive measurements is implemented to decrease the variance. Either an average and dump method or a moving average can be used for this purpose. When using the average and dump method, the averaging can be performed with only one cumulative memory location per minimum. Another advantage is that an erroneous output will likely only appear for one output time. A disadvantage is that the number of minima for the averaging must be found before each subsequent output is produced. Though more memory space is required, the advantage of the moving average is that after several initial values have been averaged, a new output is produced for each new minimum that is generated. Currently eight values are averaged for each water level that is output. From the time that the microcontroller starts to the time of the first output, about 88 seconds elapse. A new averaged value is then output every 11 seconds because the moving average is being used.

The analog outputs are produced by using the Pulse Width Modulation (PWM) outputs produced by the Tattletale microcontroller and passing them through a single pole low-pass filter. The frequency of the modulated output is 4 kHz for a 16-MHz clock speed. This value is found by generating one clock cycle of the PWM output for every 4000 system clock cycles. The high time of the pulse can be adjusted from 1 to 4000 for a corresponding full range change in the duty cycle. The components that are used for the filter are a series 910-k resistor and a shunt 1-μH capacitor. The analog outputs vary by about 1 mV for every one half-millimeter change in water level over the 2-m range of the sensory line.

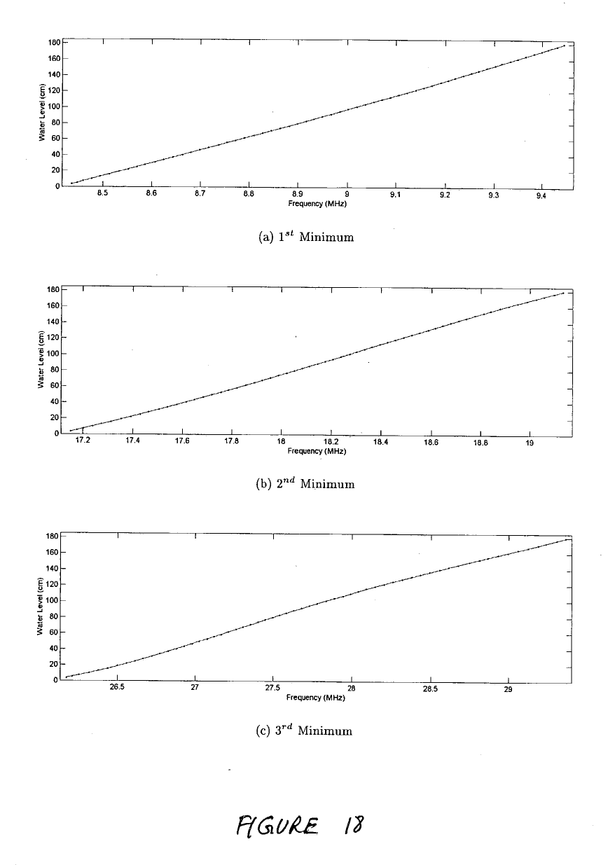

In order to find the relationship between the range of the frequency minima and the corresponding water level, a large set of measurements needs to be made. There are several reasons for performing a calibration. One reason is to find the relationship of water level as a function of frequency for given lengths of coaxial and sensory line. Another is to reduce the error due to the non-ideality of the system components. At known water levels, usually about 3 mm apart over the range of the sensory line's length, the value of each of the first three frequency minima is measured. Several measurements at each water level are averaged to try to find a mean value for each minimum and to generate data sufficiently accurate for a least squares fit to be performed. A set of this data shows the nearly linear relationship between frequency and water level. By using a least squares linear fit, the nonlinearity of the data can be noted as in FIG. 17. When using a higher order curve fit, the water level is more closely approximated. The use of a 4th order curve fit reduces the error as compared to the actual water level to a value less than 3 mm over the whole range of water levels. To find the curve fitting coefficients, the equations are set up as shown in the following equations:

$${A}_{m} = [ \begin{matrix}{f}_{m1}^{4} & {f}_{m1}^{3} & {f}_{m1}^{2} & {f}_{m1} & 1 \\ {f}_{m2}^{4} & {f}_{m2}^{3} & {f}_{m2}^{2} & {f}_{m2} & 1 \\ ⋮ & ⋮ & ⋮ & ⋮ & ⋮ \\ {f}_{mn}^{4} & {f}_{mn}^{3} & {f}_{mn}^{2} & {f}_{mn} & 1\end{matrix} ] {c}_{m} = [ \begin{matrix}{c}_{m4} \\ {c}_{m3} \\ {c}_{m2} \\ {c}_{m1} \\ {c}_{m0}\end{matrix} ] d = [ \begin{matrix}{d}_{1} \\ {d}_{2} \\ ⋮ \\ {d}_{n}\end{matrix} ]$$

where AmCm=d. The Am matrix is composed of powers of each minimum frequency at a specific water depth with subscripts m=1, 2, 3 corresponding to the first three minima. Each value of d corresponds to a known water depth. The coefficients for each minimum are found as

cₘ=(Aₘ^{T}Aₘ)⁻¹Aₘ^{T}d

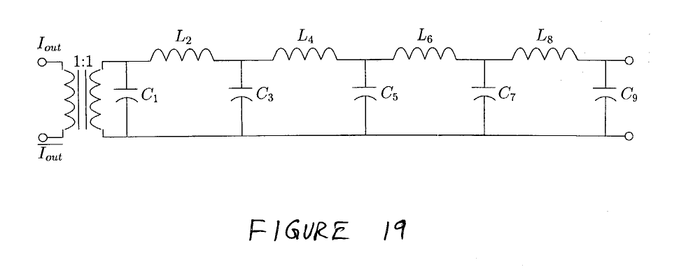

with the pseudo-inverse appearing explicitly. The same calibration data are shown with a 4th order curve fit in FIG. 18.

The calibration is worthwhile, but quite tedious. Automation of the calibration is difficult because the water levels must be known for each of the measurements. A method of performing the calibration is to add a known amount of water to a container of uniform diameter on a fixed time interval. The measurements for each known water level are then used to acquire the calibration coefficients generated by a curve fit on the data. Though this is not the most trivial of solutions, it could potentially allow several systems to be calibrated simultaneously. This would aid in a manufacturing setting.

Potential sources of error in measured values are shaking of the sensory line, changes in temperature, and noisy environments. One potential method of overcoming noise is to smooth the data by averaging several subsequent standing wave values while finding the tentative minimum. Another is to find the global minimum over the range of possible minima given the length of the coaxial cable and ladder line. Because the ranges for the first three minima do not overlap due to the current line lengths, finding the global minimum within a local range has been chosen.

Some potential explanations for the excessive noise on the standing wave are a noisy switching voltage supply, or a large amount of ambient noise from other equipment, fans, or electronics that is being received by the sensory line. At this point, the next attempt to localize the problem is to use a battery for the 5-VDC supply. The lack of noise generated by a battery would quickly enable the system to either function properly, or continue with the same noise as before. If the noise is still present, then the method making use of the algorithm to find the global minimum is suggested.

Several improvements can be made to the system as it currently stands. Some of the modifications address the issue of speed while others can potentially increase the accuracy and resolution.

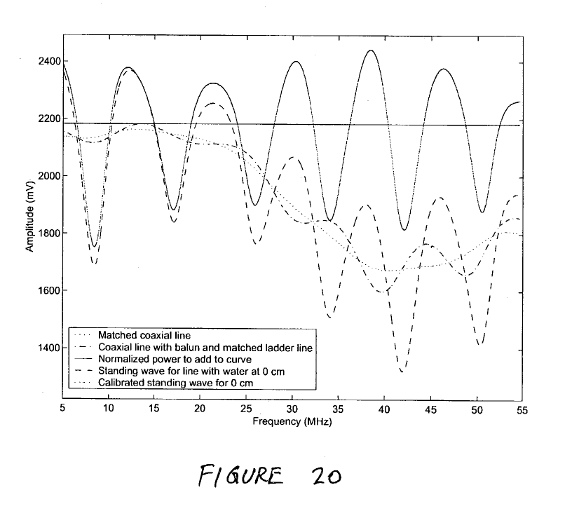

A very beneficial component to add to the system is a 1:1 transformer at the output of the synthesizer as seen in FIG. 19. The synthesizer produces a positive and negative current output to produce the desired frequency. Presently, only the positive current output is being used. The result is an output power that is quite small with a DC offset. By connecting the positive current output to one input of the transformer, and the negative current output to the other, the output power from the synthesizer will be improved by about 6 dB. Besides the substantial improvement in power, the DC offset will be removed.

The accuracy of the system comes at a cost. The calibration is tedious. In order to calibrate the system, a set of measurements must be made at increments of about 3 cm over the whole range of the line length. These data are then compiled, and a least squares curve fit is used to characterize them. When the line is adjusted or agitated, the coefficients usually change slightly but significantly. The system then performs precisely, but the accuracy is reduced. The reason for this is thought to be changes in the sensory line. Because the sensory line is currently just threaded through a pipe, bending or shaking the pipe may cause the line to become displaced, and the system accuracy would be compromised. A more rigid line setup is desired. When the line is less alterable, the accuracy will probably be less prone to change.

Because averaging is currently being used for the water level outputs, a previous water level measurement will still affect the current output for about a minute and a half. Another method to achieve the same amount of averaging but not have previous outputs affect the current output for such a long period of time is to find the tentative minimum once and then call the QR decomposition function multiple times. A majority of the time spent finding each minimum is used finding the tentative minimum. By using the faster QR function, either an average of more output values can be obtained in the same amount of time or the same number of output values can be averaged in a much shorter total time. The current assumption is that using the eight points in the average, the memory time can be reduced from 88 seconds to about 20 seconds. The system would thus adjust to changes in water level much more rapidly yet have the same small variance that results from the averaging.

Upon initial inspection, the use of more than one minimum seems redundant and time consuming. Though the use of extra minima requires more time, the robustness provided by the additional information is a benefit. The present system only utilizes three minima, but the higher order ones have a smaller variance from one output to the next. Blindly using all of the information is not suggested. For example, the fourth minimum has a discontinuity that occurs between 34 and 36 MHz in the plot of water level as a function of the frequency of the minimum. In this particular case, without some care, the minimum will likely be a hindrance instead of a benefit.

Occasionally, a minimum will be blatantly wrong. A beneficial addition to the system is to remove a minimum that is significantly different than the minimum before and after it. Without errors adversely affecting the average, a consistently accurate output is obtained.

There is a potential for a calibration to be performed that will offset the effects of a mismatch at the transformer, the losses from the coaxial line, and the system components. This can be done by measuring the standing wave of the system with the balun transformer and a length of ladder line terminated with a 400-ohm resistor. Also, the power curve generated by sweeping through the frequency range with the coaxial cable terminated in a matched impedance is measured. When the two power curves are plotted as a function of frequency, the curve from the balun transformer and matched ladder line has an increasing sinusoidal amplitude centered about the curve from the coaxial line. The reason that the sinusoidal amplitude is increasing is due to the less effective match of the balun transformer at higher frequencies. The difference between the maximum value of the power curve for the line with the balun and its curve is found and stored in memory. The effects of the system components can effectively be factored out by adding the stored difference to the standing wave of a water level measurement. The addition is possible because the RSSI chip makes measurements in decibels and represents the values as DC voltages. Normalization can thus be performed by adding the proper amount to the curve at each frequency.

FIG. 20 shows the effect of the power calibration on a representative standing wave curve for a water level of 0 cm. Though the investigation into this method has been minimal to this point, it does appear to have potential. The adjusted standing wave minima resemble the theoretical harmonic nature more closely when this method is applied. The trade-offs for using this method are memory and computation time utilized to generate a more ideal standing wave curve. The current method removes the non-ideality of the standing wave by performing the least squares curve fit to find the relationship between the frequency and the water level. Depending on the specific application, this method may be beneficial in a future revision.

If the plots of water level as a function of frequency are assumed to be sufficiently linear, a method can be used that performs all of the curve fitting simultaneously while solving for one distinct water level. This method is worth considering because the fit from each parabolic curve fit corresponds to the same water level. A change would be made in how the least squares parabolic fit is configured to incorporate all three minima and solve for the depth simultaneously. In the process, more weight can be given to a particular minimum by weighting the matrix.

An important observation to note is that prior art systems for liquid level detection have previously relied upon the liquid to dissipate the reflected energy transmitted on the conductor. It is an aspect of the present invention to dispose a resistor on the end of the conductor in order to provide impedance matching, and thus more fully dissipate the reflected.

It should also be stated, even if it has already been implied,- that those skilled in the art will now understand that a reflection at the boundary between a liquid and air is essentially the same as a reflection from the end of a conductor. Thus, all of the techniques applied to a system for determining a level of a liquid are thus equally applied to cable integrity testing, cable length, and cable impedance determination.

This application also incorporates by reference a computer program listing named APPENDIX A and sent with this application on two compact disks labeled Copy 1 and Copy 2.

It is to be understood that the above-described arrangements are only illustrative of the application of the principles of the present invention. Numerous modifications and alternative arrangements may be devised by those skilled in the art without departing from the spirit and scope of the present invention. The appended claims are intended to cover such modifications and arrangements.

What is claimed is:

1. A system for determining a location of an impedance discontinuity on a conductor by utilizing a standing wave reflectometer, said system comprising:
a processor for controlling operation of the standing wave reflectometer;
a frequency synthesizer that is controlled by the processor, and generates a transmitted signal over a range of frequencies;
an impedance matching network that is disposed to receive the transmitted signal from the frequency synthesizer;
a conductor being tested that is coupled at a first end to the impedance matching network;
at least one voltage or power measurement circuit for receiving a standing wave; and
an analog output circuit for generating an output signal representative of the location of the impedance discontinuity on the conductor.

2. The system as defined in claim 1 wherein the system further comprises a terminator coupled to a second end of the conductor so that a single reflection occurs.

3. The system as defined in claim 2 wherein at least one voltage or power measurement circuit further comprises:
a receiver signal strength indicator circuit for receiving the standing wave; and
a differential amplifier coupled to the receiver strength indicator circuit at a first end, and coupled to the processor at a second end.

4. The system as defined in claim 3 wherein the processor further comprises:
an analog-to-digital converter for receiving a signal from the differential amplifier; and
a pulse-width modulated output to the analog output circuit.

5. The system as defined in claim 4 wherein the pulse-width modulated output is replaced by a digital-to-analog converter.

6. The system as defined in claim 5 wherein the digital-to-analog converter is external to the processor.

7. The system as defined in claim 6 wherein the analog-to-digital converter is external to the processor.

8. The system as defined in claim 1 wherein the processor further comprises:
memory for storing at least one program and data; and
a floating point processor for performing analysis of the standing wave.

9. The system as defined in claim 1 wherein the frequency synthesizer is selected from the group of frequency synthesizers comprised of a Direct Digital Synthesizer (DDS) and a Phase Lock Loop (PLL) synthesizer.

10. The system as defined in claim 9 wherein the PLL further comprises a local oscillator, a phase comparator, a low-pass filter, a voltage controlled oscillator, and two digitally controlled dividers.

11. The system as defined in claim 9 wherein the DDS further comprises
an external reference clock oscillator; and
a low-pass filter for removing image frequencies that result from previous signal processing.

12. The system as defined in claim 11 wherein the low-pass filter is selected from the group of low-pass filters that utilize filter coefficients including binomial, Chebyshev, and elliptical coefficients.

13. The system as defined in claim 12 wherein the low-pass filter is a 9^{th} order Chebyshev filter that enables some ripple in a pass band, and therefore has a relatively fast cutoff.

14. The system as defined in claim 1 wherein the at least one voltage or power measurement circuit for receiving a standing wave is selected from the group of circuits comprised of a detector diode coupled to an integrating capacitor, a root mean square (RMS) to direct current (DC) converter circuit, a super diode circuit, and a Receiver Signal Strength Indicator (RSSI) circuit.

15. The system as defined in claim 1 wherein the impedance matching network that is disposed to receive the transmitted signal from the frequency synthesizer is selected from the group of impedance matching networks comprised of a Chebyshev filter, a hand wound transfer, and a commercial transformer.

16. A method for determining a location of an impedance discontinuity on a conductor by utilizing a standing wave reflectometer, said method comprising the steps of:
(1) providing a processor, a frequency synthesizer, an impedance matching network, a conductor being tested, at least one voltage or power measurement circuit, and an analog output circuit for generating an output signal representative of the location of the impedance discontinuity on the conductor;
(2) terminating the conductor so that a single reflection will occur;
(3) transmitting a plurality of frequencies onto the conductor, wherein a sum of the transmitted frequencies and reflected signals generates a standing wave as a function of frequency;
(4) determining a plurality of minima of the standing wave; and
(5) correlating the plurality of minima to a location of the impedance discontinuity on the conductor.

17. The method as defined in claim 16 wherein the method further comprises the step of utilizing the plurality of minima to determine a level of a liquid.

18. The method as defined in claim 17 wherein the method further comprises the step of calibrating the system so that the plurality of minima correspond to the level of the liquid.

19. The method as defined in claim 18 wherein the method further comprises the step of generating control words for the frequency synthesizer by utilizing the processor.

20. The method as defined in claim 19 wherein the method further comprises the step of determining a plurality of minima on the standing wave by sampling the at least one voltage or power measurement circuit.

21. The method as defined in claim 20 wherein the method further comprises the step of selecting the frequency synthesizer by choosing a frequency synthesier that can generate a plurality of different frequencies at a consistent power level.

22. The method as defined in claim 21 wherein the method further comprises the step of selecting the frequency synthesizer through a consideration of factors including a desired frequency range of operation, a smallest required step between frequencies to be generated, the necessary output power, and the method that will be used to tune between frequencies.

23. The method as defined in claim 22 wherein the method further comprises the step of selecting a low-pass filter that is coupled to the frequency synthesizer that enables the frequency synthesizer to use a maximum output range of frequencies.

24. The method as defined in claim 23 wherein the method of selecting a low-pass filter further comprises the steps of:
(1) determining desirable characteristics of the low-pass filter;
(2) selecting a low-pass filter from available filter coefficients;
(3) converting from a low-pass to a high-pass, a band pass, or a notch filter if necessary; and
(4) scaling the coefficients so that a desired cutoff frequency or pass band is achieved.

25. The method as defined in claim 17 wherein the step of selecting the at least one voltage or power measurement circuit further comprises the steps of:
(1) selecting a receiver signal strength indicator circuit for receiving the standing wave, wherein the receiver signal strength indicator circuit is selected having a high impedance input value so as not to adversely affect the power being transmitted on the conductor; and
(2) coupling a differential amplifier to the receiver strength indicator circuit at a first end, and coupling the differential amplifier to the processor at a second end.

26. The method as defined in claim 25 wherein the method further comprises the step of providing at least one additional buffer circuit at an input of the receiver signal strength indicator circuit, while compensating for additional harmonics that arise from use of the at least one additional buffer circuit.

27. The method as defined in claim 26 wherein the method further comprises the steps of:
(1) providing the processor with an analog-to-digital converter for receiving a signal from the differential amplifier; and
(2) providing the processor with a pulse-width modulated output to the analog output circuit.

28. The method as defined in claim 26 wherein the method further comprises selecting the frequency synthesizer from the group of frequency synthesizers comprised of a Direct Digital Synthesizer (DDS) and a Phase Lock Loop (PLL) synthesizer.

29. The method as defined in claim 28 wherein the method further comprises the step of running a computer program that is stored by the processor, wherein the computer program enables determination of the plurality of minima of the standing wave.

30. The method as defined in claim 29 wherein the method further comprises the steps of:
(1) sampling a digital representation of the standing wave at each of the plurality of minima;
(2) locating tentative and curve fitting minima at each of the plurality of minima;
(3) calculating the location of the discontinuity utilizing predetermined coefficients; and
(4) outputting analog values representative of the detected location of the discontinuity.

31. The method as defined in claim 30 wherein the method of locating a tentative minima further comprises the step of finding a global minimum in a local range.

32. The method as defined in claim 30 wherein the method of locating a tentative minima further comprises the step of sweeping through the frequency range while the standing wave values are decreasing until the standing wave curve starts to increase.

33. The method as defined in claim 30 wherein the method further comprises the step of compensating for the presence of noise by curve fitting to remove the discreteness from measurements.

34. The method as defined in claim 33 wherein the method further comprises the step of utilizing the tentative minima to perform a parabolic curve fit function by the steps of:
(1) defining a center point for data to be taken; and
(2) making a plurality of standing wave measurements at discrete frequencies around the center point.

35. The method as defined in claim 34 wherein the method further comprises the steps of:
(1) storing values of the plurality of minima that are returned from the parabolic fit function; and
(2) calculating the location of the discontinuity utilizing calibration coefficients.

36. A system for determining a level of a liquid utilizing a standing wave reflectometer, said system comprising:
a processor for controlling operation of the standing wave reflectometer and for determining the level of the liquid;
a frequency synthesizer that is controlled by the processor, and generates a transmitted signal over a range of frequencies;
a test line that is at least partially disposed in a liquid at a second end, and having a first end that is disposed to receive the transmitted signal from the frequency synthesizer;
a standing wave measurement circuit for measuring at least one characteristic of a reflected standing wave from the test line; and
a converter for receiving the at least one characteristic of the reflected standing wave and generating a digital signal that is representative of a point along the second end of the test line where the test line enters the liquid.

37. The system as defined in claim 36 wherein the system further comprises:
analog output circuitry for filtering a pulse width modulated signal; and
the processor, wherein the processor receives the digital signal from the converter, and generates the pulse width modulated signal that is filtered by the analog output circuitry.

38. A method for determining a level of a liquid utilizing a standing wave reflectometer, said method comprising the steps of:
(1) providing a processor, a frequency synthesizer, a test line that is at least partially disposed in a liquid at a second end, and having a first end that is disposed to receive a transmitted signal from the frequency synthesizer, a standing wave measurement circuit for receiving a reflected standing wave from the test line, and a converter for generating a signal that is representative of a point along the second end of the test line where the test line enters the liquid;
(2) generating at least one frequency on the test line to produce a standing wave;
(3) generating a digital representation of the standing wave;
(4) determining a plurality of curve fitted minima of the digital representation of the standing wave; and
(5) determining a location of the point along the test line where the test line enters the liquid to thereby determine the level of the liquid.

39. A method for determining integrity of a cable under test utilizing standing wave reflectometry, said method comprising the steps of:
(1) generating at least one frequency on the cable under test to thereby produce a standing wave;
(2) receiving a reflected standing wave from the cable under test;
(3) generating a digital representation of the reflected standing wave;
(4) determining a plurality of curve fitted minima of the digital representation of the reflected standing wave; and
(5) determining a location along the cable under test where there is an interruption in uniformity.
